(19) United States
(12) Patent Application Publication
(10) Pub. No.: US 2024/0038718 A1
(43) Pub. Date: Feb. 1, 2024

(54) Semiconductor Package and Method

(71) Applicant: Taiwan Semiconductor Manufacturing Co., Ltd., Hsinchu (TW)

(72) Inventors: Jeng-Nan Hung, Taichung City (TW); Chih-Hang Tung, Hsinchu (TW); Chen-Hua Yu, Hsinchu (TW)

(21) Appl. No.: 17/815,088

(22) Filed: Jul. 26, 2022

(51) Int. Cl. H01L 23/00; H01L 23/48; H01L 21/768; H01L 25/065

(52) U.S. Cl. CPC H01L 24/80; H01L 24/08; H01L 23/481; H01L 21/76898; H01L 25/0657; H01L 25/0652; H01L 24/96; H01L 24/97; H01L 24/94; H01L 21/561

(57) ABSTRACT

A method includes directly bonding a first wafer to a second wafer, wherein the bonding electrically connects a first interconnect structure of the first wafer to a second interconnect structure of the second wafer; directly bonding first semiconductor devices to the second wafer, wherein the bonding electrically connects the first semiconductor devices to the second interconnect structure; encapsulating the first semiconductor devices with a first encapsulant; and forming solder bumps over the first semiconductor devices.

### BACKGROUND

The packages of integrated circuits are becoming increasingly more complex, with more device dies packaged in the same package to achieve more functions. For example, a package structure has been developed to include a plurality of device dies such as processors and memory cubes in the same package. The package structure can include device dies formed using different technologies and have different functions bonded to the same device die, thus forming a system. This may save manufacturing cost and optimize device performance. Some of the device dies in the die stack may include through-silicon vias for electrical connection purpose.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, and 9 illustrate cross-sectional views of intermediate stages in the formation of a wafer package, in accordance with some embodiments.

FIGS. 10A and 10B illustrate cross-sectional views of wafer packages, in accordance with some embodiments.

FIGS. 11 and 12 illustrate the cross-sectional views of intermediate stages in the formation of a singulated package, in accordance with some embodiments.

FIGS. 13, 14, and 15 illustrate cross-sectional views of wafer packages, in accordance with some embodiments.

FIGS. 16 and 17 illustrate the cross-sectional views of intermediate stages in the formation of a wafer package incorporating a stacked device, in accordance with some embodiments.

FIGS. 18, 19, 20, 21, and 22 illustrate cross-sectional views of intermediate stages in the formation of a wafer package, in accordance with some embodiments.

FIG. 23 illustrates a cross-sectional view of a singulated package, in accordance with some embodiments.

FIGS. 24, 25, 26, and 27 illustrate cross-sectional views of wafer packages, in accordance with some embodiments.

FIG. 28 illustrates a cross-sectional view of an intermediate stage in the formation of a wafer package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Packages and the method of forming the same are provided in accordance with some embodiments. The packages described herein include wafers and device dies bonded together. For example, the packages described herein include combinations of device dies bonded to wafers, wafers bonded to wafers, wafers connected to device dies, and/or multiple tiers of device dies. In this manner, the techniques described herein may allow for both Wafer-on-Wafer (WoW) bonding and Chip-on-Wafer (CoW) bonding to be utilized in the formation of a single package. The techniques described herein can allow for packages to be manufactured with reduced process cost, reduced process steps, or reduced process time. The techniques described herein can also allow for improved design flexibility and reduced package size.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

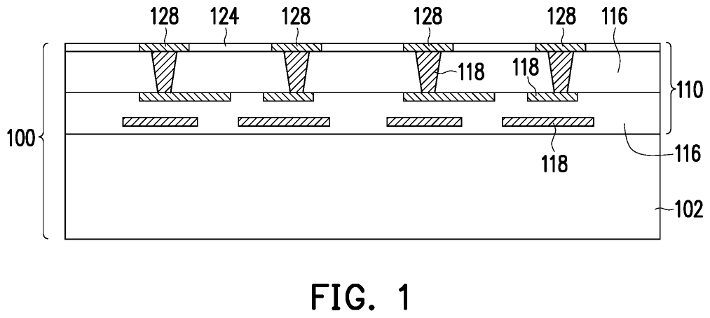

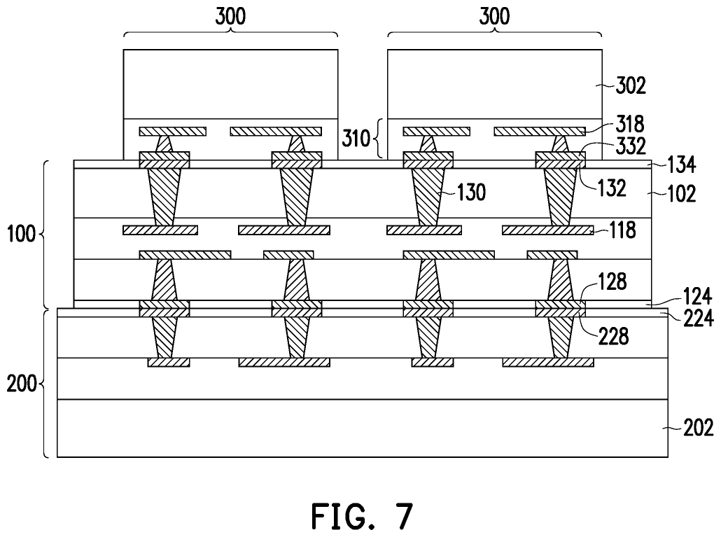

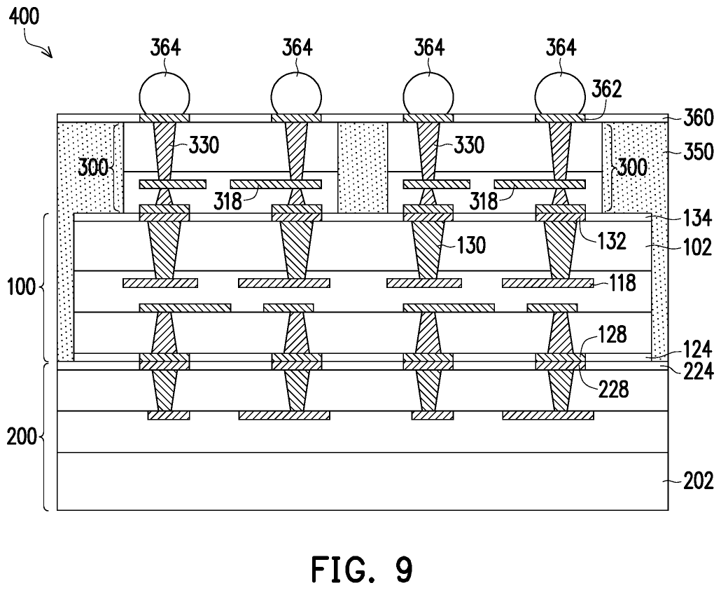

FIGS. 1 through 9 illustrate the cross-sectional views of intermediate stages in the formation of a wafer package 400 (see FIG. 9), in accordance with some embodiments of the present disclosure. FIG. 1 illustrates a cross-sectional view of a first wafer 100, in accordance with some embodiments. The first wafer 100 may include integrated circuitry and/or interconnections, and may provide functionality such as logic, memory, processing, or other functionality similar to those described below for a semiconductor device 300 (see FIG. 7).

The first wafer 100 includes a substrate 102, which may be a semiconductor substrate in some embodiments. For example, the substrate 102 may be a silicon wafer or silicon substrate, doped or undoped, or an active layer of a semiconductor-on-insulator (SOI) substrate. The substrate 102 may include other semiconductor materials, such as germanium; a compound semiconductor including silicon carbide, gallium arsenic, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The substrate 102 may have an active surface (e.g., the surface facing upwards in FIG. 1), sometimes called a front side, and an inactive surface (e.g., the surface facing downwards in FIG. 1), sometimes called a back side. Devices (not shown) may be formed at the front surface of the substrate 102. The devices may include active devices (e.g., transistors, diodes, etc.) and/or passive devices (e.g., capacitors (e.g., deep-trench capacitors or other types of capacitors), resistors, etc.). In some embodiments, the substrate 102 is free of active and/or passive devices.

An interconnect structure 110 may be formed over the front side of the substrate 102 to form electrical interconnections and to electrically and physically couple devices. The interconnect structure 110 may include conductive features 118 formed in dielectric layers 116. FIG. 1 schematically illustrates conductive features 118, which may represent suitable conductive features such as metallization patterns, contact plugs, metal lines, vias, metal pads, metal pillars, or the like. The conductive features 118 may be formed of a conductive material, such as a metal, such as copper, cobalt, aluminum, gold, combinations thereof, or the like. The dielectric layers 116 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like; a polymer such as polybenzoxazole (PBO), polyimide, a benzocyclobuten (BCB) based polymer, or the like; a nitride such as silicon nitride or the like; an oxide such as silicon oxide or the like; the like, or a combination thereof. The dielectric layers 116 may include low-k dielectric layers. In some embodiments, the dielectric layers 116 may include inter-layer dielectric (ILD) layers or inter-metal (IMD) layers. The interconnect structure 110 may be formed by a damascene process, such as a single damascene process, a dual damascene process, or the like. Other materials, features, or formation techniques are possible.

In some embodiments, the interconnect structure 110 of the first wafer 100 includes bonding pads 128 formed in a bonding layer 124. The bonding pads 128 may be physically and electrically connected to conductive features 118. The bonding pads 128 and bonding layer 124 may be used for bonding the first wafer 100 to other structures such other wafers or to semiconductor devices. For example, the bonding layer 124 may be used for a bonding process such as direct bonding, fusion bonding, dielectric-to-dielectric bonding, oxide-to-oxide bonding, or the like. The bonding pads 128 may be used for a bonding process such as direct bonding, fusion bonding, metal-to-metal bonding, or the like. In some embodiments, the bonding layer 124 and the bonding pads 128 are both utilized for bonding the first wafer 100 to other structures, such as using “hybrid bonding.” In this manner, the bonding layer 124 and the bonding pads 128 may form the “bonding surfaces” of the wafer first 100.

In some embodiments, the bonding layer 124 is formed of a silicon-containing dielectric material such as silicon oxide, silicon nitride, silicon oxynitride, or the like. The bonding layer 124 may be deposited using any suitable method, such as ALD, CVD, PVD, or the like. The bonding pads 128 may be formed using any suitable technique, such as damascene, dual damascene, or the like. As an example, the bonding pads 128 may be formed by first forming openings (not separately illustrated) within the bonding layer 124. The openings may be formed, for example, by applying and patterning a photoresist over the top surface of the bonding layer 124, then etching the bonding layer 124 using the patterned photoresist as an etching mask. The bonding layer 124 may be etched by dry etching (e.g., reactive ion etching (RIE), neutral beam etching (NBE), or the like), wet etching, or the like. Other techniques of forming the openings are possible. Conductive material may then be deposited in the openings to form the bonding pads 128, in some embodiments. In an embodiment, the conductive material may comprise a barrier layer, a seed layer, a fill metal, or a combination thereof. The barrier layer may comprise titanium, titanium nitride, tantalum, tantalum nitride, the like, or a combination thereof, and may be blanket deposited. The seed layer may be a conductive material such as copper and may be blanket deposited over the barrier layer using a suitable process, such as sputtering, evaporation, plasma-enhanced chemical vapor deposition (PECVD), or the like. The fill metal may be a conductive material such as copper, copper alloy, aluminum, or the like, and may be deposited using a suitable process, such as electroplating, electroless plating, or the like. The fill metal may fill or overfill the openings, in some embodiments. Once the fill metal has been deposited, excess material of the fill metal, the seed layer, and the barrier layer may be removed using, for example, a planarization process such as a chemical-mechanical polish (CMP) process After the planarization process, top surfaces of the bonding layer 124 and the bonding pads 128 may be substantially level or coplanar.

However, the above described embodiment in which the bonding layer 124 is formed, patterned to have openings, and the conductive material of the bonding pads 128 is plated into openings before being planarized is intended to be illustrative and is not intended to be limiting upon the embodiments. Rather, any suitable method of formation of the bonding layer 124 or the bonding pads 128 may be utilized. For example, in other embodiments, the conductive material of the bonding pads 128 may be formed first using, for example, a photolithographic patterning and plating process. The dielectric material of the bonding layer 124 may then be deposited to gap-fill the area around the bonding pads 128. A planarization process may then be performed to remove excess material. In other embodiments, the bonding pads 128 may be formed using separate processing steps. Any suitable manufacturing processes are fully intended to be included within the scope of the embodiments.

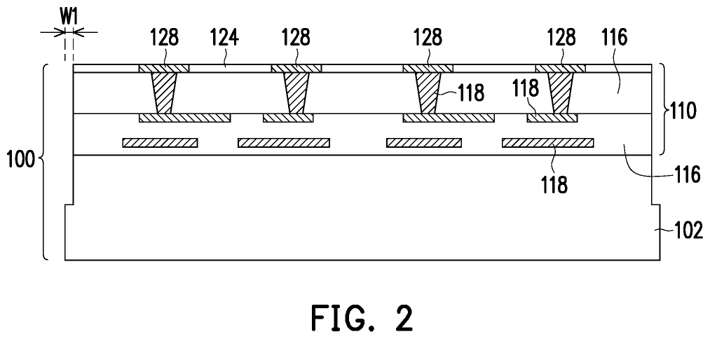

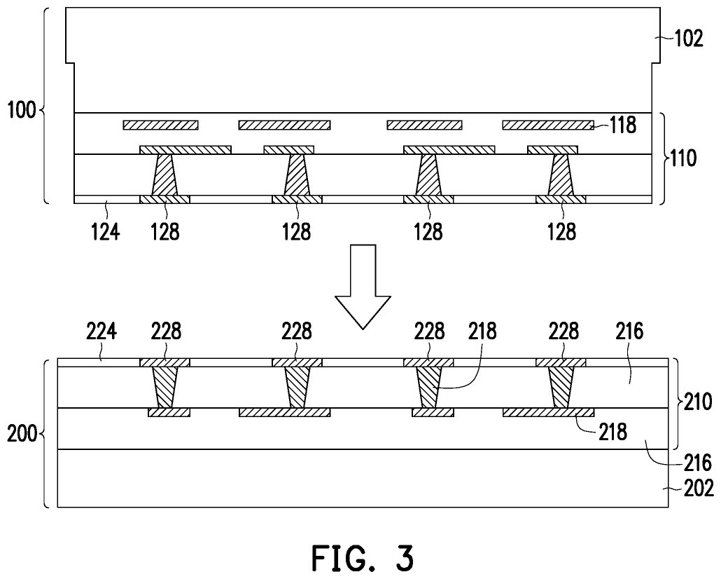

In FIG. 2, an optional trimming process is performed on the edges of the first wafer 100, in accordance with some embodiments. The trimming process may laterally recess some or all of the sidewalls of the first wafer 100, which may reduce the chance of cracking or warping as the first wafer 100 is bonded to another structure, such as to the second wafer 200 described below for FIG. 3. The trimming process may laterally recess upper sidewalls of the first wafer 100, which may partially recess sidewalls of the substrate 102, as shown in FIG. 2. The trimming process may laterally recess the first wafer 100 a width W1 that is in the range of about 0.1 mm to about 3 mm, though other distances are possible.

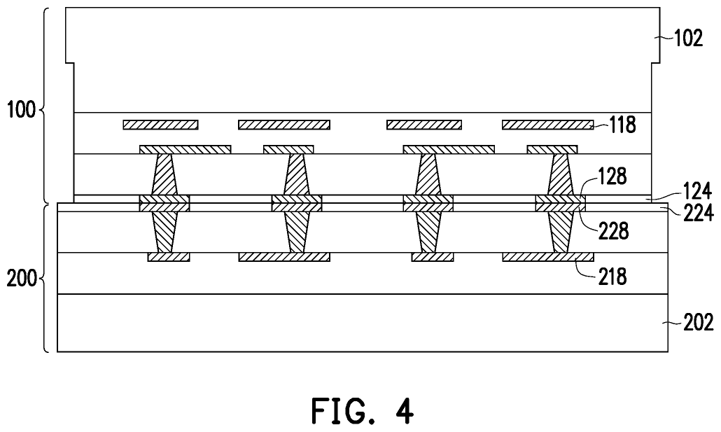

In FIGS. 3 and 4, the first wafer 100 is bonded to a second wafer 200, in accordance with some embodiments. FIG. 3 shows the first wafer and 100 the second wafer 200 prior to bonding, and FIG. 4 shows the first wafer 100 and the second wafer 200 after bonding. The first wafer 100 and the second wafer 200 may be referred to as a “wafer stack” when bonded together, in some cases. The second wafer 200 may include integrated circuitry and/or interconnections, and may provide functionality such as logic, memory, processing, or other functionality similar to those described below for a semiconductor device 300 (see FIG. 7). The second wafer 200 may include an interconnect structure 210 formed on a substrate 202, for example. The substrate 202 may be formed of materials similar to those described previously for the substrate 102, in some embodiments. For example, the substrate 202 may be a semiconductor wafer, and may include active devices and/or passive devices formed thereon. The interconnect structure 210 may be may be formed using similar materials or techniques as the interconnect structure 110 described previously for the first wafer 100, in some embodiments. For example, the interconnect structure 210 may include conductive features 218 formed in dielectric layers 216. The interconnect structure 210 may also include bonding pads 228 formed in a bonding layer 224, which may be formed using similar materials or techniques as the bonding pads 128 and bonding layer 124 described previously for the first wafer 100. The bonding layer 224 and the bonding pads 228 are used for bonding the first wafer 100 to the second wafer 200, described in greater detail below.

In some embodiments, the first wafer 100 is bonded to the second wafer 200 using, for example, dielectric-to-dielectric bonding, metal-to-metal bonding, or a combination thereof (e.g., “hybrid bonding”). In some cases, the bonding process may be a “wafer-on-wafer” bonding process or the like. In some embodiments, an activation process may be performed on the bonding surfaces of the first wafer 100 (e.g., the bonding layer 124 and the bonding pads 128) on the bonding surfaces of the second wafer 200 (e.g., the bonding layer 224 and the bonding pads 228) prior to bonding. Activating the bonding surfaces of the first wafer 100 and the second wafer 200 may comprise a dry treatment, a wet treatment, a plasma treatment, exposure to an inert gas plasma, exposure to H₂, exposure to N₂, exposure to O₂, a combination thereof, or the like. For embodiments in which a wet treatment is used, an RCA cleaning may be used. In other embodiments, the activation process may comprise other types of treatments. The activation process may facilitate bonding of the first wafer 100 and the second wafer 200.

After the activation process, the bonding surfaces of the first wafer 100 may be placed into contact with the bonding surfaces of the second wafer 200. For example, the bonding layer 124 of the first wafer 100 may be placed into physical contact with the bonding layer 224 of the second wafer 200, and the bonding pads 128 of the first wafer 100 may be placed into physical contact with corresponding bonding pads 228 of the second wafer 200. In some cases, the bonding process between bonding surfaces begins as the bonding surfaces physically contact each other.

In some embodiments, a thermal treatment is performed after the bonding surfaces are in physical contact. The thermal treatment may strengthen the bonding between the first wafer 100 and the second wafer 200, in some cases. The thermal treatment may include a process temperature in the range of about 200° C. to about 400° C., though other temperatures are possible. In some embodiments, the thermal treatment includes a process temperature that is at or above a eutectic point for a material of the bonding pads 128 or the bonding pads 228. In this manner, the first wafer 100 and the second wafer 200 are bonded using dielectric-to-dielectric bonding and/or metal-to-metal bonding. After bonding, the second wafer 200 may have a width larger than that of the first wafer 100, and some sidewall surfaces of the second wafer 200 may protrude laterally beyond sidewall surfaces of the first wafer 100, in some cases.

Additionally, while specific processes have been described to initiate and strengthen the bonds between the first wafer 100 and the second wafer 200, these descriptions are intended to be illustrative and are not intended to be limiting upon the embodiments. Rather, any suitable combination of baking, annealing, pressing, or other bonding processes or combination of processes may be utilized. All such processes are fully intended to be included within the scope of the embodiments.

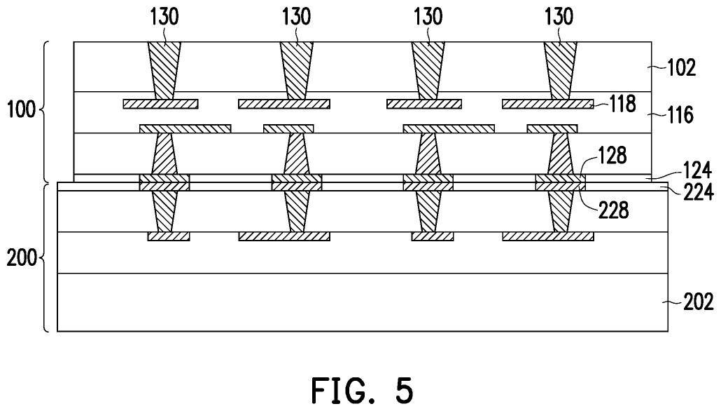

In FIG. 5, the substrate 102 of the first wafer 100 is thinned, and through vias 130 are formed, in accordance with some embodiments. Thinning the substrate 102 may include removing portions of the substrate 102 using a grinding process, a CMP process, an etching process, the like, or a combination thereof. After thinning the substrate 102, through vias 130 may be formed extending through the substrate 102 to physically and electrically contact conductive features 118 of the interconnect structure 110. In this manner, the through vias 130 may be considered “through-substrate vias” in some cases. The through vias 130 may extend into one or more dielectric layers 116 of the interconnect structure 110, in some cases. The through vias 130 may be formed, for example, by etching openings (not separately illustrated) through the substrate 102 (and through one or more dielectric layers 116, if applicable) to expose conductive features 118. A barrier layer such as titanium nitride, tantalum nitride, or the like may be deposited in the openings, and then a conductive material such as copper, tungsten, or the like, is filled into the openings. A planarization process such as a CMP process or the like is then performed to remove excess portions of the conductive material, leaving the through vias 130.

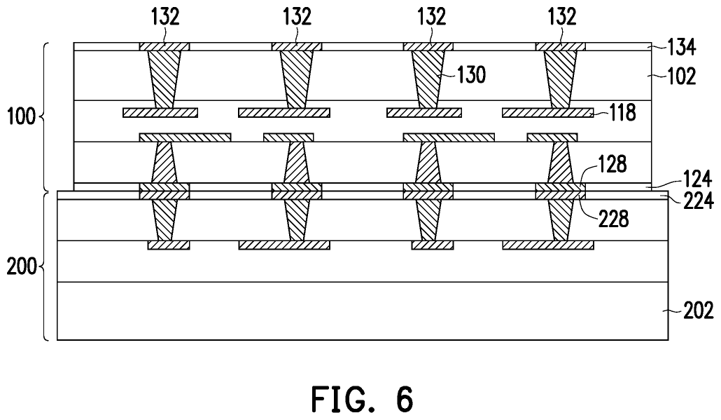

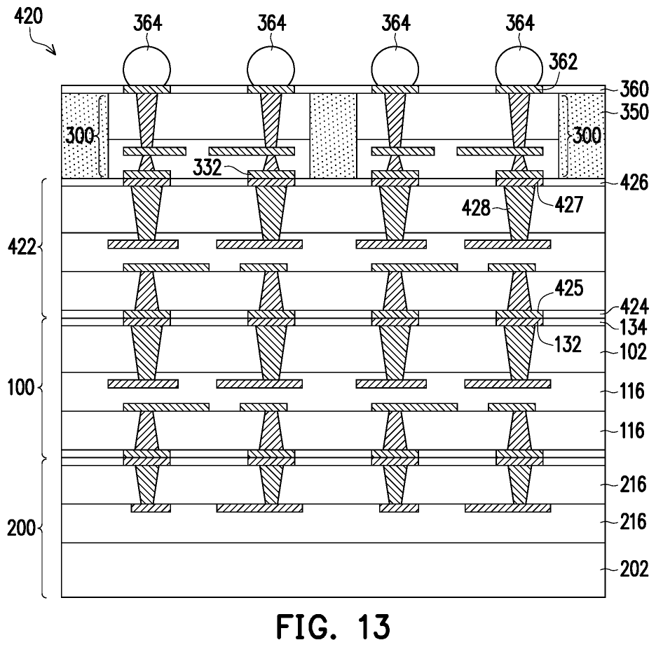

In FIG. 6, bonding pads 132 and a bonding layer 134 are formed on the first wafer 100, in accordance with some embodiments. The bonding pads 132 and the bonding layer 134 are used for bonding the first wafer 100 to other structures such as semiconductor devices (e.g., semiconductor devices 300, shown in FIG. 7) or other wafers (e.g., wafer 422, shown in FIG. 13). The bonding pads 132 and the bonding layer 134 may be formed using similar materials or techniques as the bonding pads 128 and bonding layer 124 described previously. For example, the bonding layer 134 may be formed on the substrate 102, and bonding pads 132 may be formed in the bonding layer 134. The bonding pads 132 may make physical and electrical contact with the through vias 130.

In FIG. 7, semiconductor devices 300 are bonded to the first wafer 100, in accordance with some embodiments. Any suitable number or types of semiconductor devices 300 may be bonded to the first wafer 100 in any suitable arrangement. The semiconductor devices 300 bonded to the first wafer 100 may be similar types of devices or different types of devices. A semiconductor device 300 may be, for example, a chip, a die, an integrated circuit device, or the like. For example, a semiconductor device 300 may be a logic device (e.g., Central Processing Unit (CPU), Graphics Processing Unit (GPU), Field Programmable Gate Array (FPGA), Application Specific Integrated Circuit (ASIC), Input-Output (10), Network Processing Unit (NPU), Tensor Processing Unit (TPU), Artificial Intelligence (AI) engine, microcontroller, etc.), a memory device (e.g., dynamic random access memory (DRAM), static random access memory (SRAM), wide I/O memory, NAND memory, Resistive Random Access Memory (RRAM), Magneto-resistive Random Access Memory (MRAM), Phase Change Random Access Memory (PCRAM), etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or a combination thereof (e.g., a system-on-a-chip (SoC) die).

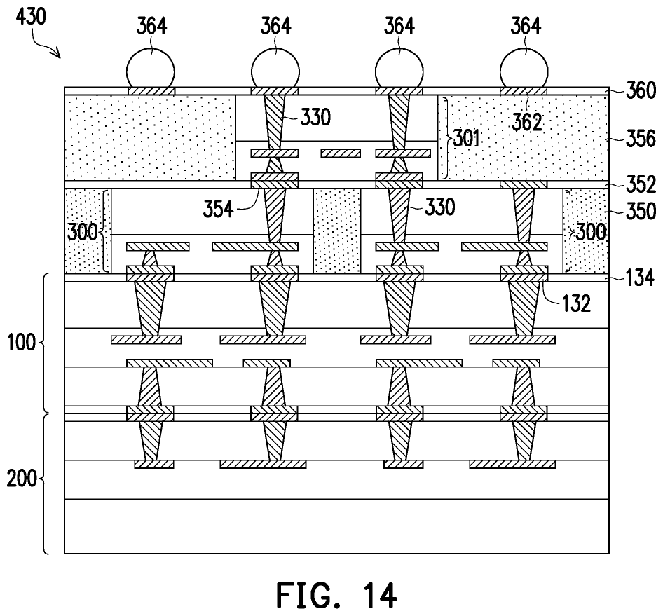

In some embodiments, a semiconductor device is a stacked device that includes multiple semiconductor substrates. For example, a semiconductor device may be a memory device that includes multiple memory dies such as a Hybrid Memory Cube (HMC) device, a High Bandwidth Memory (HBM) device, or the like. In some embodiments, a semiconductor device includes multiple semiconductor substrates interconnected by through-substrate vias (TSVs) such as through-silicon vias. Some illustrative examples of various semiconductor devices bonded to the first wafer 100 are shown in FIGS. 14 through 17, described in greater detail below. Other types or configurations of semiconductor devices 300 are possible.

In some embodiments, a semiconductor device 300 includes a substrate 302, which may include active devices and/or passive devices formed thereon. An interconnect structure 310 including conductive features 318 and one or more dielectric layers (not separately illustrated) may be formed on the substrate 302, and may interconnect the active devices and/or passive devices. The interconnect structure 310 may include bonding pads 332 formed in a bonding layer (not separately illustrated), which are used for bonding to the first wafer 100. For example, the bonding layer may be bonded to the bonding layer 134 using direct bonding, fusion bonding, dielectric-to-dielectric bonding, oxide-to-oxide bonding, or the like, and the bonding pads 332 may be bonded to the bonding pads 132 using direct bonding, fusion bonding, metal-to-metal bonding, or the like. A semiconductor device 300 may be formed using any suitable materials and techniques, which may include those described previously for the first wafer 100.

In accordance with some embodiments, the semiconductor devices 300 are placed over and bonded to the first wafer 100 using direct bonding (e.g., dielectric-to-dielectric bonding, metal-to-metal bonding, hybrid bonding, or the like). In some cases, the bonding process may be a “chip-on-wafer” bonding process or the like. The bonding process may be similar to the bonding process described previously for FIGS. 3-4. The bonding may be at wafer level. Accordingly, one semiconductor device 300 or a plurality of semiconductor devices 300 (which may be identical to each other or different from each other) are bonded to the first wafer 100. Notably, the semiconductor devices 300 are bonded to the first wafer 100 without the use of solder connections (e.g., microbumps or the like). By directly bonding the semiconductor devices 300 to the first wafer 100, advantages can be achieved, such as finer bump pitch; small form factor packages by using hybrid bonds; smaller bonding pitch scalability for chip I/O to realize high density die-to-die interconnects; improved mechanical endurance; improved electrical performance; reduced defects; and increased yield. Further, shorter die-to-die interconnections may be achieved between the semiconductor devices 300, which has the benefits of smaller form-factor, higher bandwidth, improved power integrity (PI), improved signal integrity (SI), and lower power consumption.

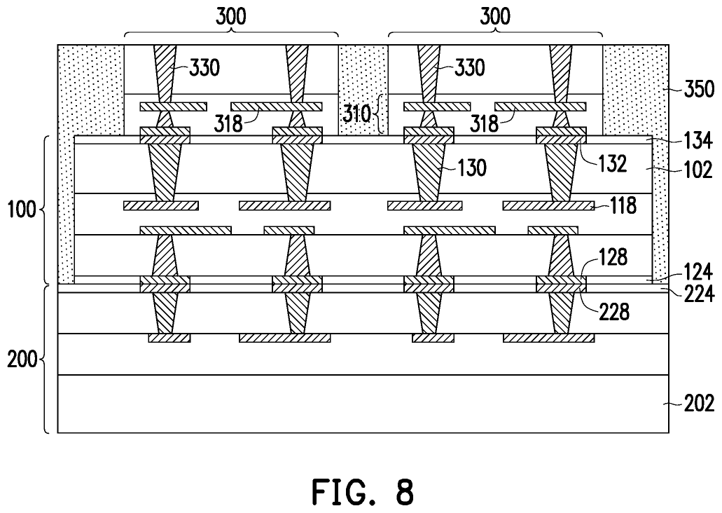

In FIG. 8, an encapsulant 350 is formed on and around the various components, in accordance with some embodiments. After formation, the encapsulant 350 encapsulates the semiconductor devices 300 and may encapsulate the first wafer 100. The encapsulant 350 may be a molding compound, epoxy, a spin-on glass (SOG), or the like. The encapsulant 350 may be applied by compression molding, transfer molding, or the like, and may be formed over the second wafer 200 such that semiconductor devices 300 are buried or covered. The encapsulant 350 is further formed in gap regions between the semiconductor devices 300. In some embodiments, the encapsulant 350 may cover sidewall surfaces of the first wafer 100 and/or top surfaces of the second wafer 200. The encapsulant 350 may be applied in liquid or semi-liquid form and then subsequently cured.

Still referring to FIG. 8, a planarization process may be performed on the encapsulant 350 to expose the semiconductor devices 300. The planarization process may also remove material of the semiconductor devices 300, in some embodiments. Top surfaces of the semiconductor devices 300 and the encapsulant 350 may be substantially level or coplanar after the planarization process (within process variations). The planarization process may include, for example, a CMP process, a grinding process, or the like. In some embodiments, the planarization may be omitted, for example, if the semiconductor devices 300 are already exposed.

Further in FIG. 8, through vias 330 are formed in the semiconductor devices 300, in accordance with some embodiments. The through vias 330 may be formed extending through the substrate 302 to physically and electrically contact conductive features 318 of the interconnect structure 310. In this manner, the through vias 330 may be considered “through-substrate vias” in some cases. The through vias 330 may extend into one or more dielectric layers of the interconnect structure 310, in some cases. The through vias 330 may be formed using materials or techniques similar to those described previously for the through vias 130, in some embodiments. For example, the through vias 330 may be formed by etching openings (not separately illustrated) through the substrate 302 (and through one or more dielectric layers, if applicable) to expose conductive features 318. A barrier layer such as titanium nitride, tantalum nitride, or the like may be deposited in the openings, and then a conductive material such as copper, tungsten, or the like, is filled into the openings. A planarization process such as a CMP process or the like is then performed to remove excess portions of the conductive material, leaving the through vias 330. Other materials or techniques are possible.

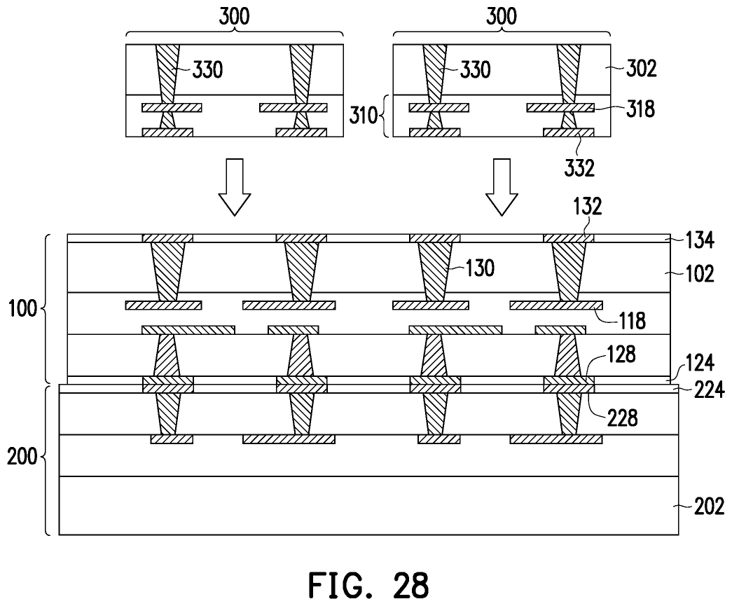

In other embodiments, the through vias 330 are formed in the semiconductor devices 300 before the semiconductor devices 300 are bonded to the first wafer 100. This is illustrated in FIG. 28, which shows semiconductor devices 300 prior to their being bonded to the first wafer 100, in which through vias 330 have been formed in the semiconductor device 300. The through vias 330 may be similar to the through vias 330 of FIG. 8, and may be formed using similar techniques. In some embodiments, the through vias 330 may be formed in the semiconductor devices 300 prior to singulation of the semiconductor devices 300 into separate semiconductor devices 300. In some embodiments, some semiconductor devices 330 may have through vias 330 formed prior to bonding, and some semiconductor devices 330 may have through vias 330 formed after bonding. In other embodiments, through vias 330 are not formed in one or more of the bonded semiconductor devices 300.

Turning to FIG. 9, conductive connectors 364 are formed for external connection to the wafer package 400, in accordance with some embodiments. In some embodiments, a passivation layer 360 may be formed over the semiconductor devices 300 and encapsulant 350. The passivation layer 360 may be a dielectric layer, and may be formed using materials or techniques such as those previously described for the dielectric layers 116. Conductive pads 362 may be formed extending through the passivation layer 360 to make physical and electrical contact with the through vias 330, in some embodiments. The conductive pads 362 may be under-bump metallizations (UBMs). In some embodiments, the conductive pads 362 have bump portions on and extending along the major surface of the dielectric layer 136, and have via portions extending through the passivation layer 360 to physically and electrically couple the through vias 330. As a result, the conductive pads 362 are electrically coupled to the through vias 330 and the semiconductor devices 300. The conductive pads 362 may be formed of the same material(s) as the conductive features 118 of the interconnect structure 110, and mat be formed using similar techniques, though other materials or techniques are possible. In other embodiments, an interconnect structure (e.g., comprising conductive features) may be formed between the through vias 330 and the conductive pads 362.

Still referring to FIG. 9, conductive connectors 364 may be formed on the conductive pads 362, in accordance with some embodiments. The conductive connectors 364 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 364 may include a conductive material such as solder, copper, aluminum, gold, nickel, silver, palladium, tin, the like, or a combination thereof. In some embodiments, the conductive connectors 364 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 364 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In this manner, a wafer package 400 may be formed, in accordance with some embodiments. As shown in FIG. 9, the encapsulant 350 may cover sidewalls of semiconductor device(s) 300 and/or the first wafer 100 of a wafer package 400. In other embodiments, the sidewalls of semiconductor device(s) 300 and/or the first wafer 100 may be exposed, examples of which are described in greater detail below for Figures Forming a wafer package 400 by directly bonding wafers (e.g., wafers 100 and 200) together as described herein can allow for more efficient manufacturing of packages. For example, functionality may be provided by integrated circuits formed within the wafer(s) rather than by separately manufactured semiconductor chips. By forming the functionality within the wafer(s), the number of manufacturing steps may be reduced, in some cases. Forming wafer packages as described herein can also allow for more flexibility in device design and allow for increased functionality within a package.

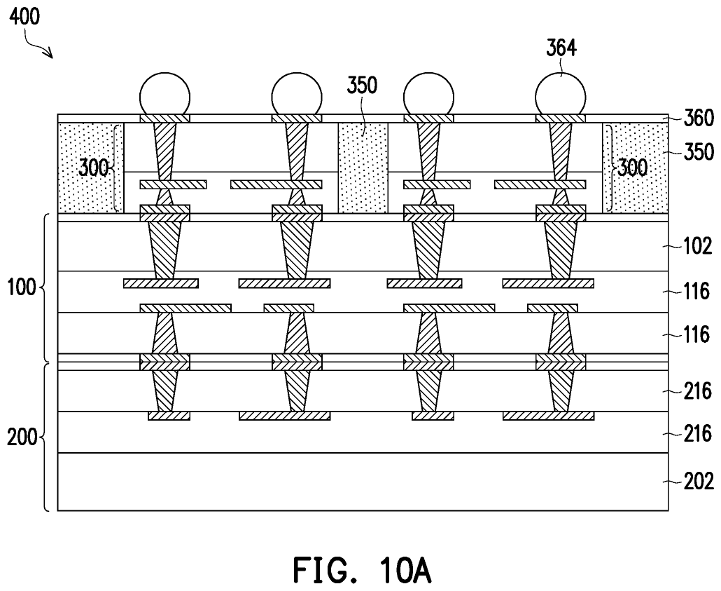

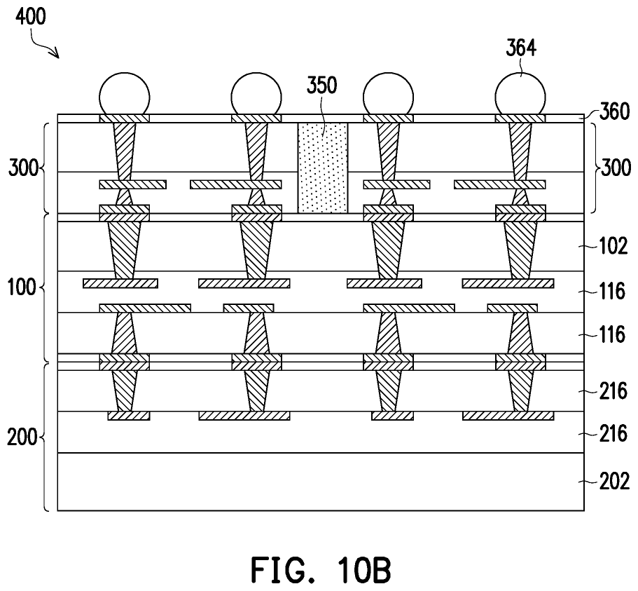

In some embodiments, a trimming process may be performed on a wafer package 400 to remove sidewall portions or edge portions of the structure, which can reduce the overall footprint of the wafer package 400. The trimming process may include, for example, a sawing process or the like. Examples of trimmed wafer packages 400 are illustrated in FIGS. 10A and 10B. The wafer package 400 illustrated in FIG. 10A is similar to the wafer package 400 illustrated in FIG. 9, except that the trimming process has removed encapsulant 350 covering the sidewalls of the first wafer 100. In this manner, the sidewalls of the first wafer 100 are exposed and are free of the encapsulant 350. As shown in FIG. 10A, sidewalls of the first wafer 100, sidewalls of the second wafer 200, and/or sidewalls of the encapsulant 350 may be coplanar or coterminous after performing the trimming process. The wafer package 400 illustrated in FIG. 10B is similar to the wafer package 400 illustrated in FIG. 9, except that the trimming process has removed encapsulant 350 covering the sidewalls of the first wafer 100 and covering some outer sidewalls of some semiconductor devices 300. In this manner, the sidewalls of the first wafer 100 are exposed and are free of the encapsulant 350, and some outer sidewalls of some semiconductor devices 300 are exposed and are free of the encapsulant 350. As shown in FIG. 10B, sidewalls of the first wafer 100, sidewalls of the second wafer 200, and/or sidewalls of one or more semiconductor devices 300 may be coplanar after performing the trimming process. In some cases, performing a trimming process can reduce the size of a wafer package 400 and/or reduce bending or warping of a wafer package 400.

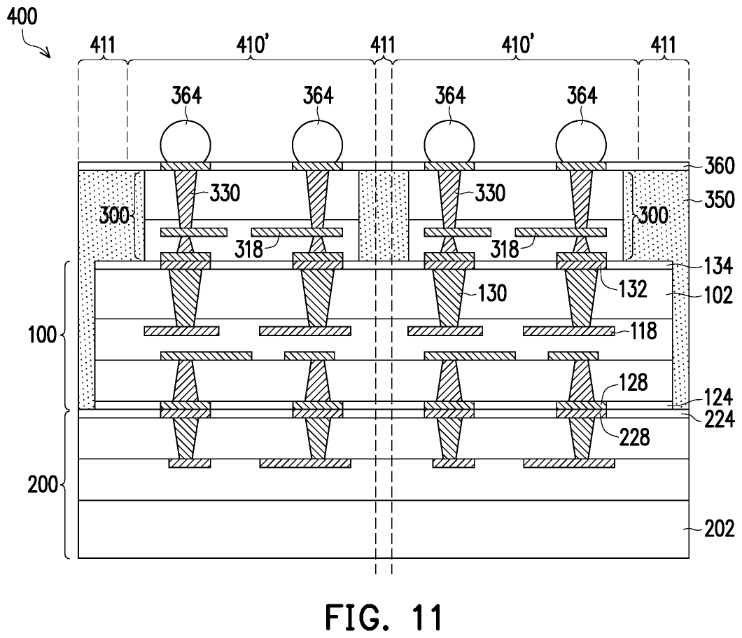

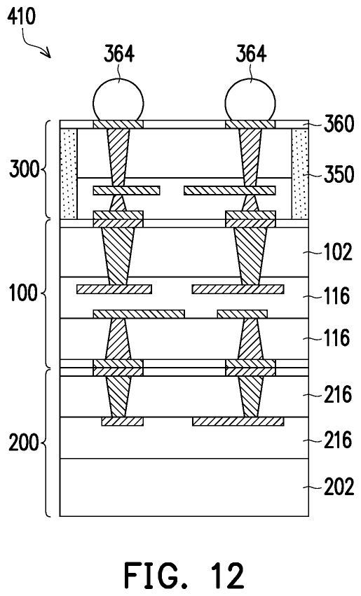

In some embodiments, a wafer package may be singulated to form individual singulated packages. This is illustrated in FIGS. 11 and 12, in which a wafer package 400 (see FIG. 11) is singulated to form separate packages 410 (see FIG. 12). The wafer package 400 may be similar to the wafer packages 400 described previously for FIGS. 9-10B, except that the wafer package 400 of FIG. 11 comprises package regions 410′ separated by scribe regions 411. Each package region 410′ corresponds to a subsequently formed package 410, and the features of respective package regions 410′ may be similar or different. Each package region 410′ may include one or more semiconductor devices 300, which may be similar or different within each package region 410′.

FIG. 12 illustrates a package 410 after the singulation process has been performed on the wafer package 400 of FIG. 11, in accordance with some embodiments. The singulation process may include a sawing process or the like that is performed along the scribe regions 411 between package regions 410′. As shown in FIG. 12, the sidewalls of the first wafer 100 of each package 410 may be free of the encapsulant 350. Accordingly, sidewalls of the first wafer 100, sidewalls of the second wafer 200, and/or sidewalls of the encapsulant 350 may be coplanar. In other embodiments, the outer sidewalls of some of the semiconductor devices 300 of a package 410 may also be free of the encapsulant 350 (not separately illustrated). Sidewalls of the first wafer 100, sidewalls of the second wafer 200, and/or sidewalls of one or more semiconductor devices 300 may be coplanar or coterminous in such embodiments. In other embodiments, the conductive connectors 364 are formed on each package 410 after singulation.

FIGS. 13 through 17 illustrate example wafer packages, in accordance with some embodiments. The wafer packages illustrated in FIGS. 13-17 may be similar to the wafer packages 400 of FIGS. 9 through 11 and/or the package 410 of FIG. 12 and may be formed using similar techniques, unless otherwise noted in the corresponding description. For example, the wafer packages illustrated in FIGS. 13-17 include a first wafer 100 directly bonded to a second wafer 200, similar to the wafer packages 400 or the package 410. In some cases, a feature described for one embodiment herein may be applied to other embodiments herein, and those skilled in the art should realize that various features of various embodiments herein may be combined, reconfigured, or rearranged while still remaining within the scope of the present disclosure. As such, the embodiments shown in FIGS. 9 through 17 are illustrated examples, and other wafer packages or singulated packages are possible. Accordingly, all suitable wafer packages, singulated packages, or variations thereof are considered within the scope of the present disclosure.

FIG. 13 illustrates a wafer package 420, in accordance with some embodiments. The wafer package 420 is similar to the wafer package 400, except that a third wafer 422 is directly bonded to the first wafer 100, and the semiconductor devices 300 are directly bonded to the third wafer 422. The first wafer 100, the second wafer 200, and the third wafer 422 may be referred to as a “wafer stack” when bonded together, in some cases. The third wafer 422 may be similar to the first wafer 100 or the second wafer 200. For example, the third wafer 422 may include an interconnect structure formed on a substrate, which may be a semiconductor wafer, in some embodiments. The third wafer 422 may include a bonding layer 424 and bonding pads 425 that are directly bonded to the bonding layer 134 and bonding pads 132 of the first wafer 100. The bonding process may be similar to the process used to bond the first wafer 100 to the second wafer 200. In some embodiments, after bonding the third wafer 422 to the first wafer 100, through vias 428 are formed in the third wafer 422. A bonding layer 426 and bonding pads 427 may be formed on the third wafer 422, and then semiconductor devices 300 may be directly bonded to the bonding layer 426 and/or bonding pads 427. Sidewalls of the third wafer 422 may be free of the encapsulant 350.

Semiconductor devices 300 may be bonded to the bonding layer and/or bonding pads 427 of the third wafer 422 using techniques described previously. The semiconductor devices 300 may be encapsulated by an encapsulant 350, and through vias 330 may be formed in the semiconductor devices 300. A passivation layer 360 and conductive pads 362 may be formed over the semiconductor devices 300, and conductive connectors 364 may be formed on the conductive pads 362. In other embodiments, one or more additional wafers may be directly bonded to the third wafer 422 in a similar manner, with the semiconductor devices 300 bonded to the topmost wafer of the “wafer stack.” Accordingly, a wafer package may include a “wafer stack” comprising any suitable number of bonded wafers, with semiconductor devices 300 bonded to the topmost wafer of the wafer stack.

FIG. 14 illustrates a wafer package 430 comprising multiple tiers of semiconductor devices, in accordance with some embodiments. The wafer package 430 is similar to the wafer package 400, except that one or more semiconductor devices 301 (e.g., the “second-tier devices 301”) are placed over and connected to the semiconductor devices 300 (e.g., the “first-tier devices 300”). FIG. 14 shows two first-tier devices 300 and one second-tier device 301, but any suitable number of first-tier devices 300 or second-tier devices 301 may be used, and the devices 300/301 may have any suitable configuration or arrangement. The devices 300/301 may be similar types of devices or may be different types of devices, which may be similar to those described previously for the semiconductor devices 300. In other embodiments, additional tiers of semiconductor devices may be formed, such as a third tier of semiconductor devices placed over the second-tier devices 301. In this manner, a wafer package may comprise one or more tiers of semiconductor devices.

The first-tier devices 300 may be directly bonded to the first wafer 100 and encapsulated by an encapsulant 350, which may be similar to the process described for FIG. 8. Through vias 330 may also be formed in the first-tier devices 300, which may be similar to the through vias 330 described for FIG. 8. A bonding layer 352 may be formed over the semiconductor devices 300, and bonding pads 354 may be formed in the bonding layer 352. The bonding layer 352 and the bonding pads 354 may be formed using materials or techniques similar to those described previously, such as for the bonding layer 124 and bonding pads 128. The bonding pads 354 may be formed over and make electrical contact with the through vias 330.

The second-tier devices 301 may then be directly bonded to the bonding layer 352 and the bonding pads 354, in some embodiments. In this manner, the second-tier devices 301 may make electrical connection to the through vias 330 of the first-tier devices 300 through the bonding pads 354. A second-tier device 301 may be electrically connected to a single first-tier device 300 or to multiple first-tier devices 300. As an illustrative example, FIG. 14 shows a second-tier device 301 that is electrically connected to two separate first-tier devices 300. Other arrangements, connections, or configurations of the second-tier devices 301 are possible.

The second-tier devices 301 may then be encapsulated by an encapsulant 356, which may be similar to the encapsulant 350. Through vias 330 may then be formed in the second-tier devices 301. A passivation layer 360 and conductive pads 362 may be formed over the second-tier devices 301, and conductive connectors 364 may be formed on the conductive pads 362. The wafer package 430 is an example, and other wafer packages having multiple tiers of devices are possible.

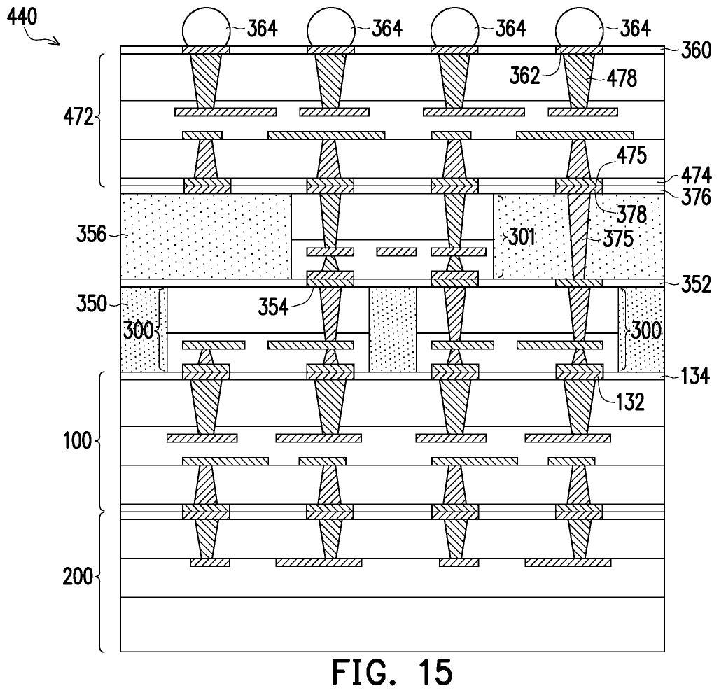

FIG. 15 illustrates a wafer package 440 comprising multiple tiers of semiconductor devices with an overlying wafer, in accordance with some embodiments. The wafer package 440 is similar to the wafer package 430 of FIG. 14, except that a third wafer 472 is directly bonded to the topmost tier of semiconductor devices (e.g., second-tier device 301 in FIG. 15). The third wafer 472 may be similar to the third wafer 422 described for FIG. 13. For example, the third wafer 372 may include through vias 478 and may include a bonding layer 474 and bonding pads 475 used for bonding and for making electrical connections. In some embodiments, a bonding layer 376 and bonding pads 378 may be formed over the second-tier device(s) 301 and the encapsulant 356. The bonding layer 474 and the bonding pads 475 of the third wafer 472 may be directly bonded to the bonding layer 376 and bonding pads 378 using direct bonding techniques such as those described previously. A passivation layer 360 and conductive pads 362 may be formed over the third wafer 472, and conductive connectors 364 may be formed on the conductive pads 362. The conductive pads 362 may make electrical connection to through vias 478 of the third wafer 472. The wafer package 440 is an example, and other wafer packages are possible. For example, in other embodiments, a wafer package may comprise more than two tiers of devices or more than one wafer bonded on top of the multiple tiers of devices.

Additionally, as an example, the wafer package 440 includes a through via 375 extending through the encapsulant 356 to make electrical connection between the third wafer 472 and a first-tier device 300. In other embodiments, a through via 375 extending through the encapsulant 356 is not present. One or more through vias may extend through a layer of encapsulant in other embodiments of the various wafer packages described in the present disclosure. In some embodiments, the through via 375 may be formed after bonding the second-tier devices 301 and encapsulating the second-tier devices 301 with the encapsulant 356. The through via 375 may be formed, for example, by etching an opening in the encapsulant 356 that exposes a bonding pad 354. Conductive material(s) may then be deposited in the opening, and a CMP process or the like may be performed to remove excess conductive material(s). Other techniques for forming a through via 375 are possible.

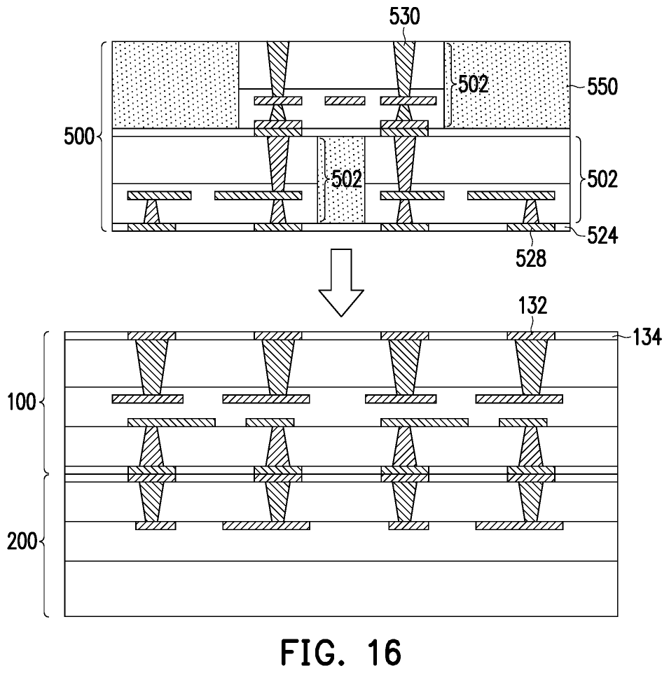

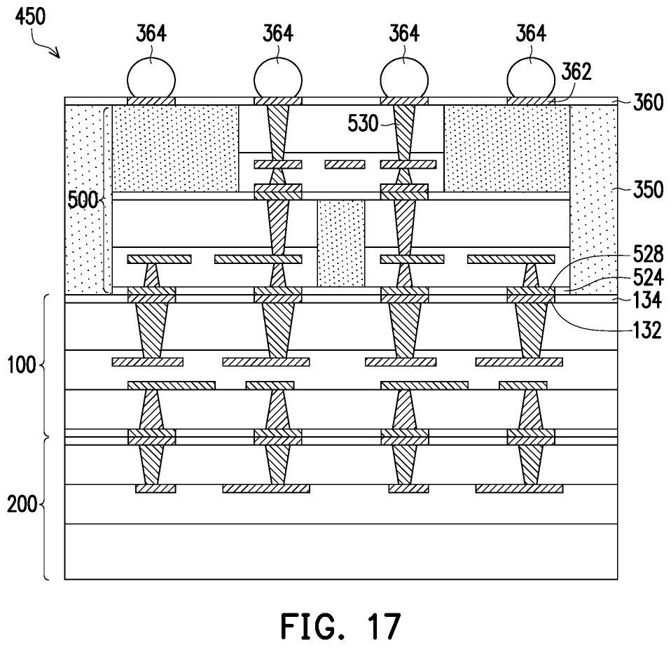

FIGS. 16 and 17 illustrate the formation of a wafer package 450 comprising a stacked device 500, in accordance with some embodiments. The wafer package 450 is similar to the wafer package 400, except that a stacked device 500 is bonded to the first wafer 100 instead of (or in addition to) the semiconductor devices 300. FIG. 16 illustrates the structure prior to bonding the stacked device 500, and FIG. 17 illustrates the wafer package 450 after performing subsequent processing steps including bonding of the stacked device 500. The stacked device 500 may be a single device or package comprising multiple semiconductor devices 502. For example, the stacked device 500 may be a System on Integrated Chip (SoIC) or the like, in some embodiments. The semiconductor devices 502 may be any suitable devices, such as those described previously for the semiconductor devices 300. A stacked device 500 may comprise any suitable number, types, configuration, or arrangement of semiconductor devices 502. The stacked device 500 may include a bonding layer 524 and bonding pads 528, which are used for bonding and making electrical connection to the first wafer 100. The bonding layer 524 may be directly bonded to the bonding layer 134, and the bonding pads 528 may be directly bonded to the bonding pads 132 using bonding techniques such as those described previously. The stacked device 500 may also include through vias 530 or other conductive features (e.g., conductive pads) that allow electrical connections to be made to the top of the stacked device 500.

FIG. 17 illustrates the wafer package 450 after bonding the stacked device 500, in accordance with some embodiments. After bonding the stacked device 500 to the first wafer 100, the stacked device 500 may be encapsulated by an encapsulant 350. A passivation layer 360 and conductive pads 362 may be formed over the stacked device 500, and conductive connectors 364 may be formed on the conductive pads 362. The conductive pads 362 may make electrical connection to through vias 530 of the stacked device 500. The wafer package 450 is an example, and other wafer packages comprising a stacked device are possible. For example, in other embodiments, a wafer package 450 may include more than one stacked device 500.

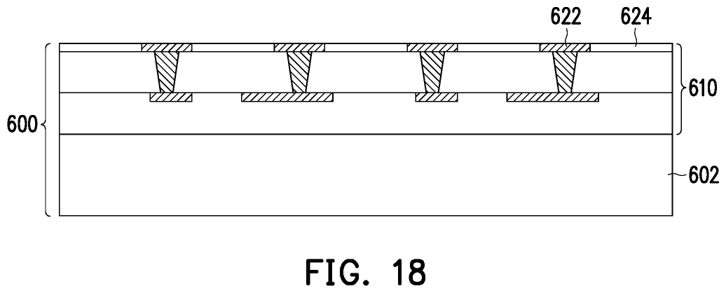

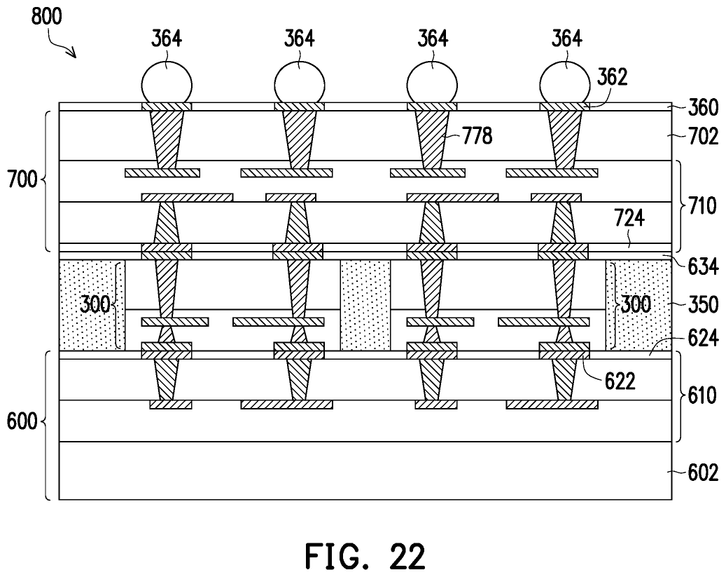

FIGS. 18 through 22 illustrate the cross-sectional views of intermediate stages in the formation of a wafer package 800 (see FIG. 22), in accordance with some embodiments of the present disclosure. The wafer package 800 is similar to the wafer package 400 shown in FIG. 9, except that semiconductor devices 300 are bonded to a first wafer before bonding additional wafers. Some of the materials or processes used in the formation of the wafer package 800 may be similar to those described for the formation of the wafer package 400 in FIGS. 1-9, and accordingly some details may not be repeated.

FIG. 18 illustrates a cross-sectional view of a first wafer 600, in accordance with some embodiments. The first wafer 600 may be similar to the first wafer 100 or the second wafer 200 described previously. For example, the first wafer 600 may include integrated circuitry formed on a substrate 602 and an interconnect structure 610. The first wafer 600 may include bonding pads 622 formed in a bonding layer 624.

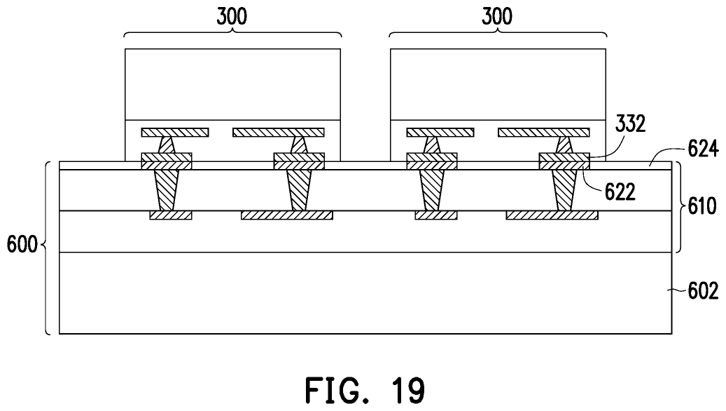

In FIG. 19, semiconductor devices 300 are directly bonded to the first wafer 600, in accordance with some embodiments. The semiconductor devices 300 may be similar types of devices or different types of devices, which may be devices similar to the examples described previously for the semiconductor devices 300. Any suitable number of semiconductor devices 300 may be bonded to the first wafer 600 in any suitable configuration or arrangement. The semiconductor devices 300 may be directly bonded to the bonding pads 622 and/or the bonding layer 624 of the first wafer 600 using dielectric-to-dielectric bonding, metal-to-metal bonding, fusion bonding, hybrid bonding, the like, or a combination thereof. The bonding process may be similar to a bonding process described previously.

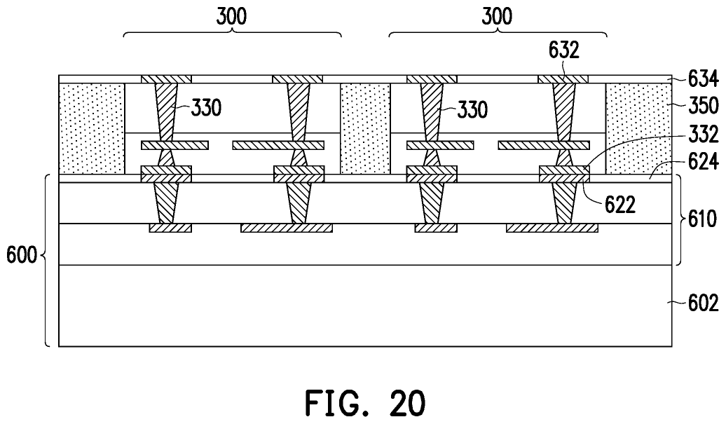

In FIG. 20, the semiconductor devices 300 are encapsulated by an encapsulant 350 and through vias 330 are formed in the semiconductor devices 300, in accordance with some embodiments. The encapsulant 350 and the through vias 330 may be formed using processes such as those described previously for FIG. 8, for example. In other embodiments, through vias may be formed extending through the encapsulant 350 and make electrical connection to the first wafer 600. FIG. 20 also illustrates the formation of bonding pads 632 and a bonding layer 634 on the semiconductor devices 300 and encapsulant 350.

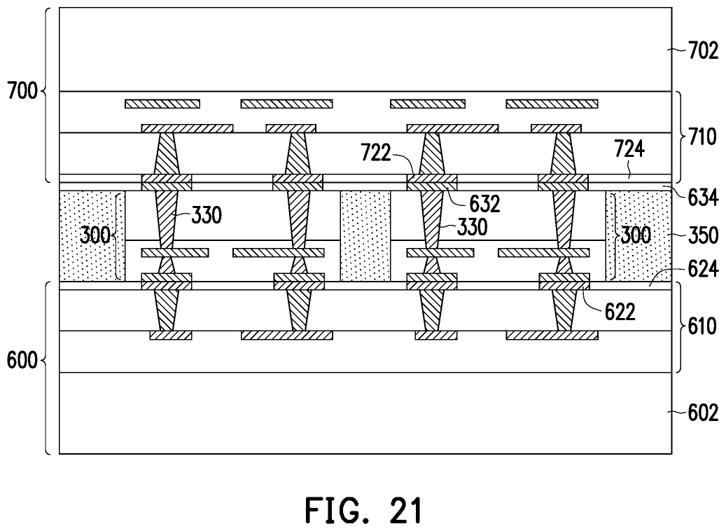

In FIG. 21, a second wafer 700 is directly bonded to the bonding pads 632 and/or bonding layer 634, in accordance with some embodiments. The second wafer 700 may be similar to the first wafer 100 or the second wafer 200 described previously. For example, the second wafer 700 may include integrated circuitry formed on a substrate 702 and an interconnect structure 710. The second wafer 700 may be directly bonded over the semiconductor devices 300 using direct bonding techniques such as those described previously. In this manner, the semiconductor devices 300 may be “sandwiched” between the two wafers 600 and 700.

FIG. 22 illustrates the wafer package 800 after forming through vias 778 and conductive connectors 364, in accordance with some embodiments. In some embodiments, the substrate 602 and/or the substrate 702 may be thinned using a grinding process, a CMP process, or the like. Through vias 778 may be formed extending through the substrate 702 and making electrical connection to the interconnect structure 710. A passivation layer 360 and conductive pads 362 may be formed over the second wafer 700, and conductive connectors 364 may be formed on the conductive pads 362. The wafer package 800 is an example, and other wafer packages are possible. In some embodiments, the wafer package 800 may be laterally thinned, similar to the embodiments described previously for FIGS. 10A-10B. In some embodiments, sidewalls of the first wafer 600, sidewalls of the encapsulant 350, and sidewalls of the second wafer 700 are coplanar or coterminous.

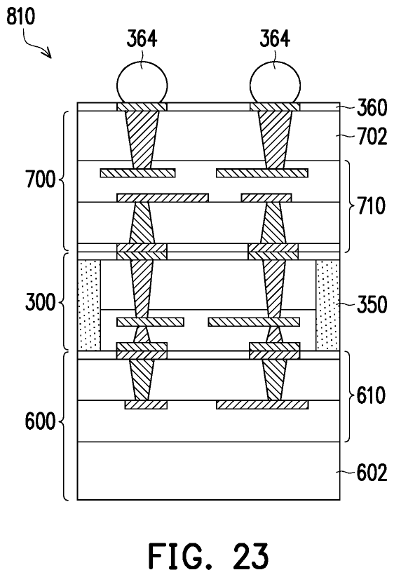

In some embodiments, a wafer package may be singulated to form individual singulated packages. This is illustrated in FIG. 23, in which a wafer package similar to wafer package 800 has been singulated to form separate packages 810. For example, the wafer package may comprise package regions separated by scribe regions (not separately illustrated), similar to the wafer package 400 shown in FIG. 11. Each package region may include one or more semiconductor devices 300, which may be similar or different within each package region. The wafer package may be singulated into packages 810 using a suitable process such as a sawing process. As shown in FIG. 23, sidewalls of the first wafer 600, sidewalls of the second wafer 700, and/or sidewalls of the encapsulant 350 may be coplanar or coterminous. In other embodiments, the outer sidewalls of some of the semiconductor devices 300 of a package 810 may also be free of the encapsulant 350 (not separately illustrated). Sidewalls of the first wafer 600, sidewalls of the second wafer 700, and/or sidewalls of one or more semiconductor devices 300 may be coplanar or coterminous in such embodiments. In other embodiments, the conductive connectors 364 are formed on each package 810 after singulation.

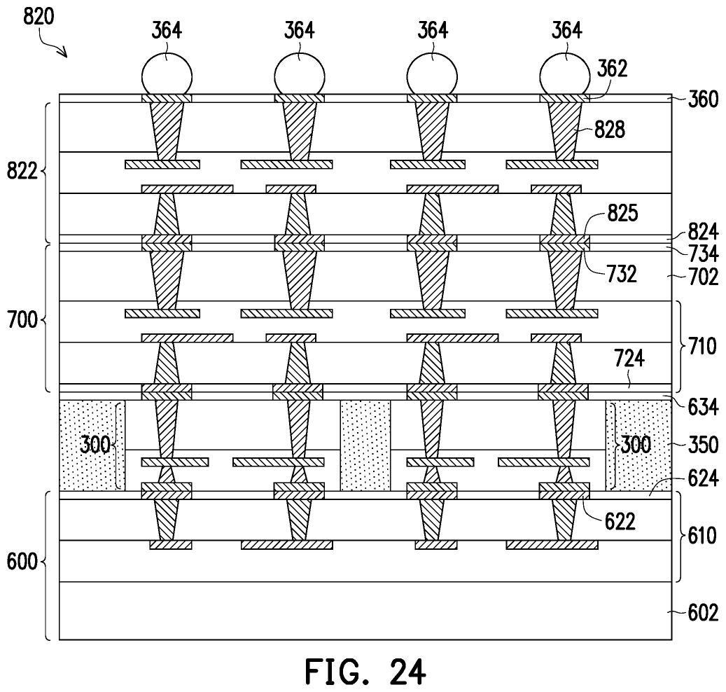

FIGS. 24 through 27 illustrate example wafer packages, in accordance with some embodiments. The wafer packages illustrated in FIGS. 24-27 may be similar to the wafer package 800 of FIG. 22 and/or the package 810 of FIG. 23 and may be formed using similar techniques, unless otherwise noted in the corresponding description. For example, the wafer packages illustrated in FIGS. 24-27 include one or more semiconductor devices directly bonded to a first wafer 600 and/or sandwiched between two wafers, similar to the wafer package 800 or the package 810. In some cases, a feature described for one embodiment herein may be applied to other embodiments herein, and those skilled in the art should realize that various features of various embodiments herein may be combined, reconfigured, or rearranged while still remaining within the scope of the present disclosure. As such, the embodiments shown in FIGS. 24 through 27 are illustrated examples, and other wafer packages or singulated packages are possible. Accordingly, all suitable wafer packages, singulated packages, or variations thereof are considered within the scope of the present disclosure.

FIG. 24 illustrates a wafer package 820, in accordance with some embodiments. The wafer package 820 is similar to the wafer package 800, except that a third wafer 822 is directly bonded to the second wafer 700. The second wafer 700 and the third wafer 822 may be referred to as a “wafer stack” when bonded together, in some cases. A bonding layer 734 and bonding pads 732 may be formed on the second wafer 700, and the third wafer 822 may include a bonding layer 824 and bonding pads 825 that are directly bonded to the bonding layer 734 and bonding pads 732 of the second wafer 700. In some embodiments, after bonding the third wafer 822 to the second wafer 700, through vias 828 are formed in the third wafer 822. A passivation layer 360 and conductive pads 362 may be formed over the third wafer 822, and conductive connectors 364 may be formed on the conductive pads 362. In other embodiments, one or more additional wafers may be directly bonded to the third wafer 822 in a similar manner. Accordingly, a wafer package may include a “wafer stack” comprising any suitable number of bonded wafers, with semiconductor devices 300 sandwiched between a wafer and the wafer stack. In other embodiments, the semiconductor devices 300 may sandwiched between two wafer stacks, each comprising two or more wafers.

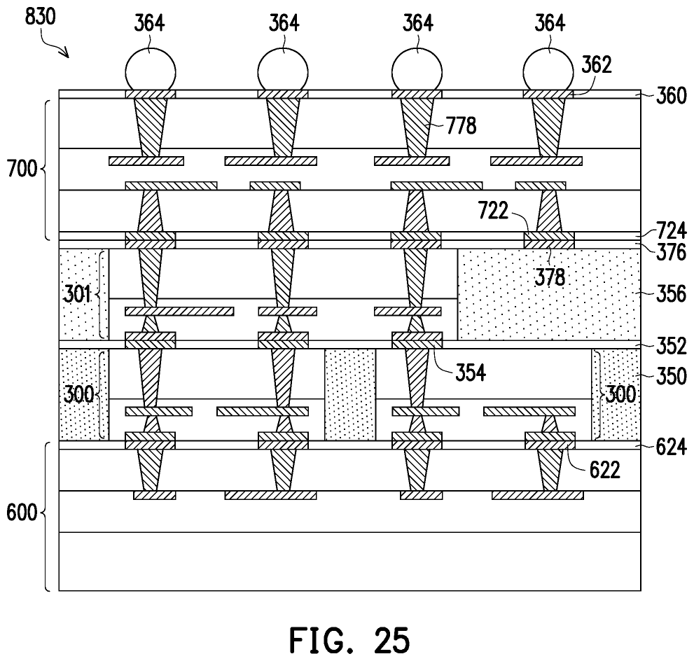

FIG. 25 illustrates a wafer package 830 comprising multiple tiers of semiconductor devices, in accordance with some embodiments. The wafer package 830 is similar to the wafer package 800, except that one or more semiconductor devices 301 (e.g., the “second-tier devices 301”) are placed over and connected to the semiconductor devices 300 (e.g., the “first-tier devices 300”). FIG. 25 shows two first-tier devices 300 and one second-tier device 301, but any suitable number of first-tier devices 300 or second-tier devices 301 may be used, and the devices 300/301 may have any suitable configuration or arrangement. The devices 300/301 may be similar types of devices or may be different types of devices, which may be similar to those described previously for the semiconductor devices 300. In other embodiments, additional tiers of semiconductor devices may be formed, such as a third tier of semiconductor devices placed over the second-tier devices 301. In this manner, a wafer package may comprise one or more tiers of semiconductor devices.

The first-tier devices 300 may be directly bonded to the first wafer 600 and encapsulated by an encapsulant 350. A bonding layer 352 may be formed over the semiconductor devices 300, and bonding pads 354 may be formed in the bonding layer 352. The second-tier devices 301 may then be directly bonded to the bonding layer 352 and the bonding pads 354, in some embodiments. A second-tier device 301 may be electrically connected to a single first-tier device 300 or to multiple first-tier devices 300. Other arrangements, connections, or configurations of the second-tier devices 301 are possible. The second-tier devices 301 may then be encapsulated by an encapsulant 356. A bonding layer 376 and bonding pads 378 may be formed over the second-tier devices 301 and the encapsulant 356. The second wafer 700 may then be directly bonded to the bonding layer 376 and bonding pads 378. For example, the bonding layer 724 of the second wafer 700 may be directly bonded to the bonding layer 376, and the bonding pads 722 of the second wafer 700 may be directly bonded to the bonding pads 378. A passivation layer 360 and conductive pads 362 may be formed over the second wafer 700, and conductive connectors 364 may be formed on the conductive pads 362. The wafer package 830 is an example, and other wafer packages having multiple tiers of devices are possible.

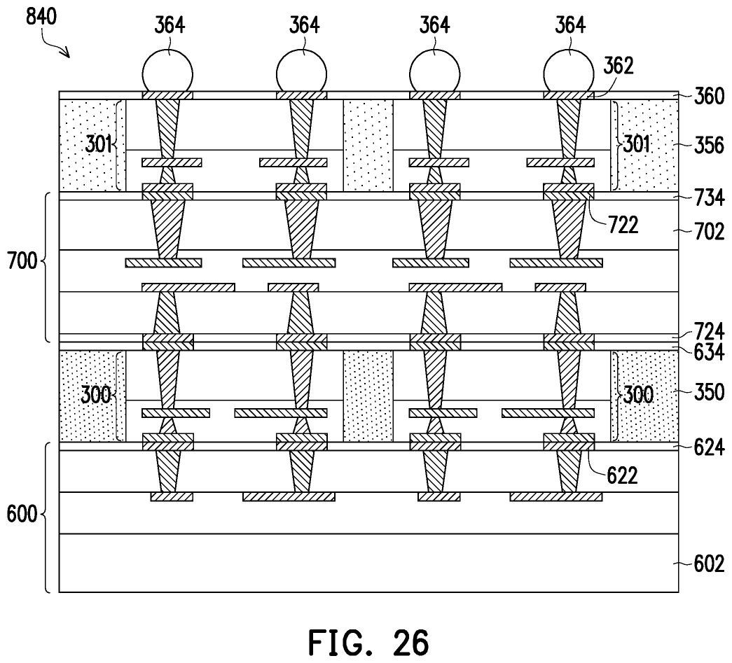

FIG. 26 illustrates a wafer package 840 comprising multiple tiers of semiconductor devices separated by wafers, in accordance with some embodiments. The wafer package 840 is similar to the wafer package 800, except that a second wafer 700 placed over and connected to the first-tier devices 300, and then one or more second-tier devices 301 are bonded to the second wafer 700. FIG. 26 shows two first-tier devices 300 and two second-tier devices 301, but any suitable number of first-tier devices 300 or second-tier devices 301 may be used, and the devices 300/301 may have any suitable configuration or arrangement. The devices 300/301 may be similar types of devices or may be different types of devices, which may be similar to those described previously for the semiconductor devices 300. For example, the first-tier devices 300 may be Hybrid Memory Cube (HMC) devices, and the second tier devices 301 may be logic devices. Other combinations of devices are possible. In other embodiments, additional tiers of semiconductor devices may be formed, such as a third tier of semiconductor devices placed over and connected to the first-tier devices 300 or the second-tier devices 301. In other embodiments, one or more wafers may be placed over and connected to the second-tier devices 301. In this manner, a wafer package may comprise one or more tiers of semiconductor devices, and tiers may be separated by one or more wafers. The wafer package 840 is an example, and other wafer packages having multiple tiers of devices are possible.

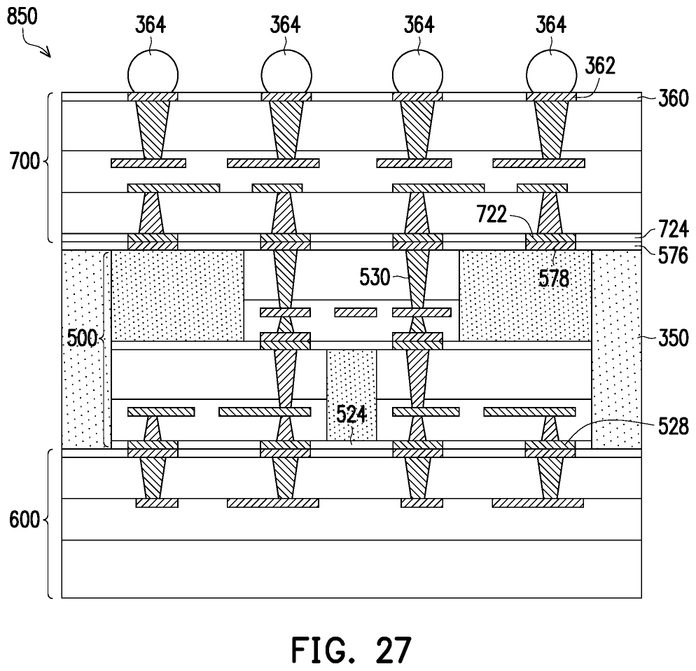

FIG. 27 illustrates a wafer package 850 comprising a stacked device 500, in accordance with some embodiments. The wafer package 550 is similar to the wafer package 800, except that a stacked device 500 is bonded to the first wafer 600 instead of (or in addition to) the semiconductor devices 300. The stacked device 500 may be similar to the stacked device 500 described previously for FIGS. 16-17. The stacked device 500 may be directly bonded to the first wafer 600 and then encapsulated by an encapsulant 350. A bonding layer 576 and bonding pads 578 may be formed over the stacked device 500 and the encapsulant, and then a second wafer 700 may be directly bonded to the bonding layer 576 and/or the bonding pads 578. The wafer package 850 is an example, and other wafer packages having multiple tiers of devices are possible.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. The wafer packages described herein utilize both wafer-to-wafer bonding and chip-to-wafer bonding, and thus may have the benefits of both Wafer-on-Wafer (WoW) structures and Chip-on-Wafer (CoW) structures. For example, using direct bonding (e.g., fusion bonding, metal bonding, hybrid bonding, or the like) can allow for shorter, less resistive, or more reliable electrical connections and also can allow for smaller package size. By forming structures on wafers and then directly bonding the wafers (e.g., using wafer-to-wafer bonding techniques or the like), manufacturing cost and manufacturing time may be reduced. For example, bonding a wafer comprising multiple integrated circuit functionalities may have reduced manufacturing cost or manufacturing time than bonding multiple chips providing the same functionalities to a wafer. The embodiments described herein allow for the flexible design of a wafer package, such as allowing various combinations of wafers and semiconductor devices to be bonded together in various arrangements.

In accordance with some embodiments of the present disclosure, a method includes directly bonding a first wafer to a second wafer, wherein the bonding electrically connects a first interconnect structure of the first wafer to a second interconnect structure of the second wafer; directly bonding first semiconductor devices to the second wafer, wherein the bonding electrically connects the first semiconductor devices to the second interconnect structure; encapsulating the first semiconductor devices with a first encapsulant; and forming solder bumps over the first semiconductor devices. In an embodiment, directly bonding the first wafer to the second wafer includes dielectric-to-dielectric bonding and metal-to-metal bonding. In an embodiment, wherein sidewalls of the second wafer are free of the first encapsulant. In an embodiment, the method includes performing a singulation process between two neighboring first semiconductor devices of the first semiconductor devices. In an embodiment, directly bonding the first semiconductor devices to the second wafer includes forming a first bonding layer and first bonding pads on the second wafer and directly bonding first semiconductor devices to the first bonding layer and the first bonding pads. In an embodiment, the method includes directly bonding a third wafer to the first wafer, wherein the bonding electrically connects a third interconnect structure of the first wafer to the first interconnect structure of the first wafer. In an embodiment, the method includes, after directly bonding the first wafer to the second wafer, forming through substrate vias in the second wafer, wherein the through substrate vias extend from an outer surface of the second wafer to the second interconnect structure of the second wafer. In an embodiment, the method includes, after directly bonding the first semiconductor devices to the second wafer, forming through vias in the first semiconductor devices; and forming a second bonding layer and second bonding pads on the first semiconductor devices. In an embodiment, the method includes directly bonding second semiconductor devices to the second bonding layer and the second bonding pads; and encapsulating the second semiconductor devices with a second encapsulant. In an embodiment, the method includes directly bonding a fourth wafer to the second bonding layer and the second bonding pads.

In accordance with some embodiments of the present disclosure, a method includes forming first bonding pads on a first side of a first semiconductor substrate; forming second bonding pads on a first side of a second semiconductor substrate; bonding the first bonding pads to the second bonding pads using a first metal-to-metal bonding process; after performing the first metal-to-metal bonding process, forming first through vias in the first semiconductor substrate; forming third bonding pads on a second side of the first semiconductor substrate, wherein the third bonding pads are electrically connected to the first through vias; bonding a semiconductor die to the third bonding pads using a second metal-to-metal bonding process; after performing the second metal-to-metal bonding process, surrounding the semiconductor die with an encapsulant; and forming second through vias in the semiconductor die. In an embodiment, the method includes, before performing the first metal-to-metal bonding process, performing a first trimming process on sidewalls of the first semiconductor substrate. In an embodiment, the method includes forming integrated circuits in the first semiconductor substrate. In an embodiment, the method includes, after surrounding the semiconductor die with the encapsulant, performing a second trimming process to remove encapsulant from sidewalls of the first semiconductor substrate. In an embodiment, the method includes forming solder bumps on the semiconductor die. In an embodiment, the first semiconductor substrate is a silicon wafer.

In accordance with some embodiments of the present disclosure, a package includes a first wafer including a first interconnect structure on a first semiconductor substrate; first semiconductor devices directly bonded to the first interconnect structure, wherein each first semiconductor device includes a through via; an encapsulant surrounding each first semiconductor device; a first bonding layer extending over the encapsulant and the first semiconductor devices; first bonding pads in the first bonding layer, wherein each first bonding pad physically and electrically contacts a respective through via of a first semiconductor device; and a second wafer including a second interconnect structure on a second semiconductor substrate, wherein the second interconnect structure is directly bonded to the first bonding layer and the first bonding pads. In an embodiment, sidewalls of the second wafer are free of the encapsulant. In an embodiment, the package includes through substrate vias in the second semiconductor substrate; a second bonding layer extending over the second semiconductor substrate; and second bonding pads in the second bonding layer, wherein each second bonding pad physically and electrically contacts a respective through substrate via. In an embodiment, the package includes second semiconductor devices directly bonded to the second bonding layer and the second bonding pads.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
directly bonding a first wafer to a second wafer, wherein the bonding electrically connects a first interconnect structure of the first wafer to a second interconnect structure of the second wafer;
directly bonding a plurality of first semiconductor devices to the second wafer, wherein the bonding electrically connects the plurality of first semiconductor devices to the second interconnect structure;
encapsulating the plurality of first semiconductor devices with a first encapsulant; and
forming solder bumps over the plurality of first semiconductor devices.

2. The method of claim 1, wherein directly bonding the first wafer to the second wafer comprises dielectric-to-dielectric bonding and metal-to-metal bonding.

3. The method of claim 1, wherein sidewalls of the second wafer are free of the first encapsulant.

4. The method of claim 1 further comprising performing a singulation process between two neighboring first semiconductor devices of the plurality of first semiconductor devices.

5. The method of claim 1, wherein directly bonding the plurality of first semiconductor devices to the second wafer comprises forming a first bonding layer and first bonding pads on the second wafer and directly bonding the plurality of first semiconductor devices to the first bonding layer and the first bonding pads.

6. The method of claim 1 further comprising directly bonding a third wafer to the first wafer, wherein the bonding electrically connects a third interconnect structure of the first wafer to the first interconnect structure of the first wafer.

7. The method of claim 1 further comprising, after directly bonding the first wafer to the second wafer, forming through substrate vias in the second wafer, wherein the through substrate vias extend from an outer surface of the second wafer to the second interconnect structure of the second wafer.

8. The method of claim 1 further comprising:
after directly bonding the plurality of first semiconductor devices to the second wafer, forming through vias in the first semiconductor devices of the plurality of first semiconductor devices; and
forming a second bonding layer and second bonding pads on the plurality of first semiconductor devices.

9. The method of claim 8 further comprising:
directly bonding a plurality of second semiconductor devices to the second bonding layer and the second bonding pads; and
encapsulating the plurality of second semiconductor devices with a second encapsulant.

10. The method of claim 8 further comprising directly bonding a fourth wafer to the second bonding layer and the second bonding pads.

11. A method comprising:
forming first bonding pads on a first side of a first semiconductor substrate;
forming second bonding pads on a first side of a second semiconductor substrate;
bonding the first bonding pads to the second bonding pads using a first metal-to-metal bonding process;
after performing the first metal-to-metal bonding process, forming first through vias in the first semiconductor substrate;
forming third bonding pads on a second side of the first semiconductor substrate, wherein the third bonding pads are electrically connected to the first through vias;
bonding a semiconductor die to the third bonding pads using a second metal-to-metal bonding process;
after performing the second metal-to-metal bonding process, surrounding the semiconductor die with an encapsulant; and
forming second through vias in the semiconductor die.

12. The method of claim 11 further comprising, before performing the first metal-to-metal bonding process, performing a first trimming process on sidewalls of the first semiconductor substrate.

13. The method of claim 11 further comprising forming integrated circuits in the first semiconductor substrate.

14. The method of claim 11 further comprising, after surrounding the semiconductor die with the encapsulant, performing a second trimming process to remove encapsulant from sidewalls of the first semiconductor substrate.

15. The method of claim 11 further comprising forming solder bumps on the semiconductor die.

16. The method of claim 11, wherein the first semiconductor substrate is a silicon wafer.

17. A package comprising:
a first wafer comprising a first interconnect structure on a first semiconductor substrate;
a plurality of first semiconductor devices directly bonded to the first interconnect structure, wherein each first semiconductor device comprises a through via;
an encapsulant surrounding each first semiconductor device of the plurality of first semiconductor devices;
a first bonding layer extending over the encapsulant and the plurality of first semiconductor devices;
a plurality of first bonding pads in the first bonding layer, wherein each first bonding pad physically and electrically contacts a respective through via of a first semiconductor device; and
a second wafer comprising a second interconnect structure on a second semiconductor substrate, wherein the second interconnect structure is directly bonded to the first bonding layer and the plurality of first bonding pads.

18. The package of claim 17, wherein sidewalls of the second wafer are free of the encapsulant.

19. The package of claim 17 further comprising:
a plurality of through substrate vias in the second semiconductor substrate;
a second bonding layer extending over the second semiconductor substrate; and
a plurality of second bonding pads in the second bonding layer, wherein each second bonding pad physically and electrically contacts a respective through substrate via.

20. The package of claim 19 further comprising a plurality of second semiconductor devices directly bonded to the second bonding layer and the plurality of second bonding pads.
